(19) United States
(12) Patent Application Publication
(10) Pub. No.: US 2015/0179834 A1
(43) Pub. Date: Jun. 25, 2015

(54) BARRIER-LESS METAL SEED STACK AND CONTACT

(71) Applicants: Mukul Agrawal, Fremont, CA (US); Seung Rim, Palo Alto, CA (US); Michael Cudzinovic, Sunnyvale, CA (US)

(72) Inventors: Mukul Agrawal, Fremont, CA (US); Seung Rim, Palo Alto, CA (US); Michael Cudzinovic, Sunnyvale, CA (US)

(21) Appl. No.: 14/137,610

(22) Filed: Dec. 20, 2013

(51) Int. Cl. H01L 31/0224; H01L 31/18; H01L 31/036; H01L 31/0312; H01L 31/0368

(52) U.S. Cl. CPC H01L 31/022425; H01L 31/0312; H01L 31/03682; H01L 31/036; H01L 31/182; H01L 31/1864

(57) ABSTRACT

Approaches for forming barrier-less seed stacks and contacts are described. In an example, a solar cell includes a substrate and a conductive contact disposed on the substrate. The conductive contact includes a copper layer directly contacting the substrate. In another example, a solar cell includes a substrate and a seed layer disposed directly on the substrate. The seed layer consists essentially of one or more non-diffusion-barrier metal layers. A conductive contact includes a copper layer disposed directly on the seed layer. An exemplary method of fabricating a solar cell involves providing a substrate, and forming a seed layer over the substrate. The seed layer includes one or more non-diffusion-barrier metal layers. The method further involves forming a conductive contact for the solar cell from the seed layer.

### TECHNICAL FIELD

Embodiments of the present disclosure are in the field of renewable energy and, in particular, include approaches for forming barrier-less metal seed stacks and contacts.

### BACKGROUND

Photovoltaic cells, commonly known as solar cells, are well known devices for direct conversion of solar radiation into electrical energy. Generally, solar cells are fabricated on a semiconductor wafer or substrate using semiconductor processing techniques to form a p-n junction near a surface of the substrate. Solar radiation impinging on the surface of, and entering into, the substrate creates electron and hole pairs in the bulk of the substrate. The electron and hole pairs migrate to p-doped and n-doped regions in the substrate, thereby generating a voltage differential between the doped regions. The doped regions are connected to conductive regions on the solar cell to direct an electrical current from the cell to an external circuit coupled thereto.

Techniques for increasing the efficiency in the manufacture of solar cells are generally desirable. Some embodiments of the present disclosure allow for increased solar cell manufacturing efficiency by providing novel processes for fabricating solar cell structures.

### BRIEF DESCRIPTION OF THE DRAWINGS

FIGS. 1A, 1B, and 1C illustrate cross-sectional views of a portion of a solar cell with conductive contacts including a copper layer directly contacting a substrate, in accordance with an embodiment of the present disclosure.

FIG. 2 illustrates a cross-sectional view of a portion of a solar cell with conductive contacts including a metal seed layer disposed on a substrate, in accordance with an embodiment of the present disclosure.

FIG. 3 illustrates a cross-sectional view of a portion of a solar cell with conductive contacts including multiple metal seed layers disposed on a substrate, in accordance with an embodiment of the present disclosure.

FIG. 4 is a flowchart illustrating operations in a method of fabricating a solar cell, in accordance with an embodiment of the present disclosure.

FIGS. 5A and 5B illustrate cross-sectional views of processing operations in a method of fabricating solar cells corresponding to operations of the flowchart of FIG. 4, and in accordance with an embodiment of the present disclosure.

FIG. 6 is a flowchart illustrating operations in a method of fabricating a solar cell, in accordance with an embodiment of the present disclosure.

FIGS. 7A, 7B, 7C, and 7D illustrate cross-sectional views of processing operations in a method of fabricating solar cells corresponding to operations of the flowchart of FIG. 6, and in accordance with an embodiment of the present disclosure.

FIG. 8A illustrates a graph of the change in leakage current density after annealing an exemplary substrate with a copper seed layer, in accordance with an embodiment of the present disclosure.

FIG. 8B illustrates a graph of the change in bulk recombination rate after annealing an exemplary substrate with a copper seed layer, in accordance with an embodiment of the present disclosure.

FIG. 8C illustrates a graph of the change in leakage current density after annealing an exemplary substrate with a copper seed layer, in accordance with an embodiment of the present disclosure.

FIG. 8D illustrates a graph of the change in bulk recombination rate after annealing an exemplary substrate with a copper seed layer, in accordance with an embodiment of the present disclosure.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary, or the following detailed description.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

Terminology. The following paragraphs provide definitions and/or context for terms found in this disclosure (including the appended claims):

“Comprising.” This term is open-ended. As used in the appended claims, this term does not foreclose additional structure or steps.

“Configured To.” Various units or components may be described or claimed as “configured to” perform a task or tasks. In such contexts, “configured to” is used to connote structure by indicating that the units/components include structure that performs those task or tasks during operation. As such, the unit/component can be said to be configured to perform the task even when the specified unit/component is not currently operational (e.g., is not on/active). Reciting that a unit/circuit/component is “configured to” perform one or more tasks is expressly intended not to invoke 35 U.S.C. §112, sixth paragraph, for that unit/component.

“First,” “Second,” etc. As used herein, these terms are used as labels for nouns that they precede, and do not imply any type of ordering (e.g., spatial, temporal, logical, etc.). For example, reference to a “first” solar cell does not necessarily imply that this solar cell is the first solar cell in a sequence; instead the term “first” is used to differentiate this solar cell from another solar cell (e.g., a “second” solar cell).

“Coupled.” The following description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Approaches for forming barrier-less metal seed stacks and contacts for solar cells and the resulting solar cells are described herein. In the following description, numerous specific details are set forth, such as specific process flow operations, in order to provide a thorough understanding of embodiments of the present disclosure. It will be apparent to one skilled in the art that embodiments of the present disclosure may be practiced without these specific details. In other instances, well-known fabrication techniques, such as copper plating techniques, are not described in detail in order to not unnecessarily obscure embodiments of the present disclosure. Furthermore, it is to be understood that the various embodiments shown in the figures are illustrative representations and are not necessarily drawn to scale.

Disclosed herein are methods of fabricating solar cells. In an embodiment, a method of fabricating a solar cell involves providing a substrate, and plating a copper layer directly onto the substrate to form a conductive contact.

In another embodiment, a method of fabricating a solar cell involves providing a substrate, and forming a seed layer over the substrate. The seed layer consists essentially of one or more non-diffusion-barrier metal layers. The method further involves forming a conductive contact for the solar cell from the seed layer.

Also disclosed herein are solar cells. In an embodiment, a solar cell includes a substrate. A conductive conduct is disposed on the substrate and includes a copper layer directly contacting the substrate.

In another embodiment, a solar cell includes a substrate. A seed layer is disposed directly on the substrate, and consists essentially of one or more non-diffusion-barrier metal layers. A conductive contact includes a copper layer disposed directly on the seed layer.

Thus, embodiments of the present disclosure include solar cells with diffusion-barrier-less conductive contacts. Existing methods of forming contacts generally involve deposition of multiple seed layers, including a diffusion barrier layer between a copper layer and the silicon. Copper diffusion into the silicon can damage devices, and therefore existing contacts include a diffusion barrier metal layer to prevent unwanted diffusion of the copper into the silicon. An example of a diffusion barrier material is a Titanium-Tungsten alloy (TiW). One example of a seed stack for forming a contact with a diffusion barrier layer includes an aluminum (Al) seed layer disposed on a silicon substrate, a TiW barrier layer disposed on the aluminum seed layer, and a copper (Cu) seed layer disposed on the TiW barrier layer. The TiW barrier layer thus limits copper diffusion into the silicon substrate.

Methods involving deposition of a barrier layer may involve additional processing steps and require complex processing tools. For example, deposition of multiple metal layers including a TiW barrier layer may necessitate a separate substrate edge coating operation to prevent metal from being deposited on the edges of the solar cell substrate. The additional processing steps involved in depositing a barrier layer can decrease throughput. In contrast to existing methods, embodiments of the disclosure include solar cell contacts without a diffusion barrier layer but that limit copper diffusion into the silicon.

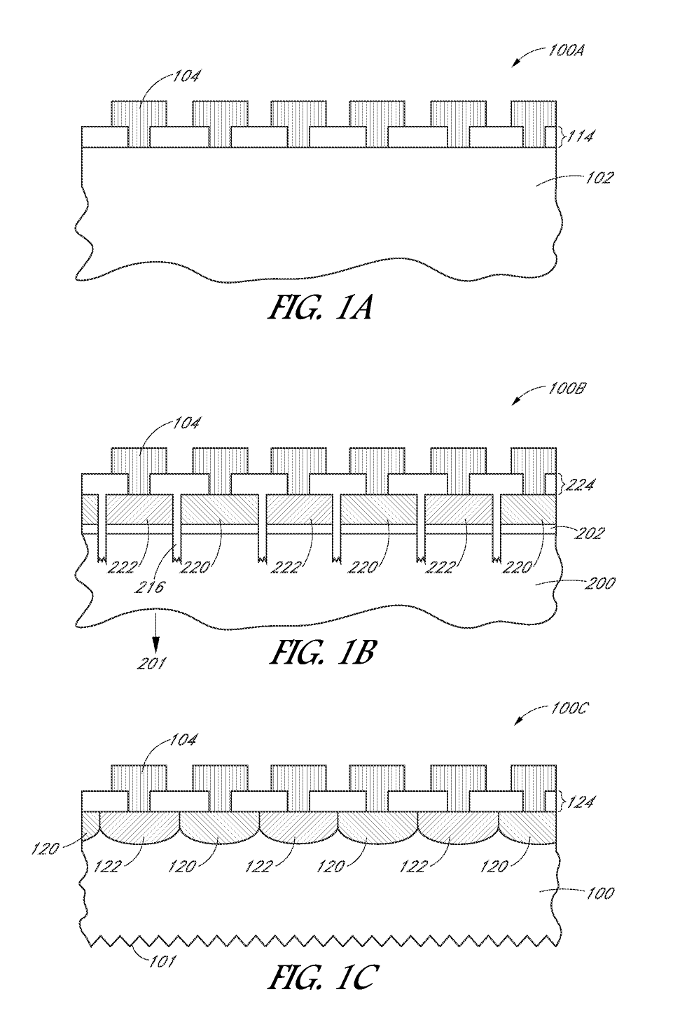

FIGS. 1A-1C, FIG. 2, and FIG. 3 illustrate cross-sectional views of solar cells in accordance with embodiments of the present disclosure.

FIG. 1A illustrates a cross-sectional view of a portion of a solar cell with conductive contacts including a copper layer directly contacting a substrate, in accordance with an embodiment of the present disclosure. A portion of the solar cell 100A includes a substrate 102. Conductive contacts 104 are disposed on the substrate 102. According to embodiments, the conductive contacts 104 include a copper layer directly contacting the substrate 102. FIG. 1A illustrates a portion of the solar cell 100A with a patterned dielectric layer 114 disposed over the substrate 102. In the illustrated embodiment, the conductive contacts 104 contact the substrate 102 through gaps or contact openings in the dielectric layer 114. The substrate 102 can include one or more semiconducting and/or dielectric layers. For example, FIGS. 1B and 1C illustrate exemplary substrates upon which the conductive contacts 104 may be disposed.

FIG. 1B illustrates a cross-sectional view of a portion of a solar cell having conductive contacts formed on emitter regions formed above a substrate, in accordance with an embodiment of the present disclosure.

Referring to FIG. 1B, a portion of a solar cell 100B includes a patterned dielectric layer 224 disposed above a plurality of n-type doped polycrystalline silicon (polysilicon) regions 220, a plurality of p-type doped polysilicon regions 222, and on portions of a substrate 200 exposed by trenches 216. The polysilicon regions 220 and 222 are formed from a polysilicon layer disposed in or above the substrate 200. According to one such embodiment, the polysilicon layer has a doping concentration in a range of at least 10¹⁸ per cm³. In one such embodiment, the doping concentration is in the range of 10¹⁹ to 10²⁰ per cm³. In one embodiment, the substrate 200 includes a monocrystalline silicon substrate. Although described as a polycrystalline silicon regions 220 and 222, in an alternative embodiment, the regions 220 and 222 are formed from an amorphous silicon layer.

The conductive contacts 104 include a copper layer that directly contacts the polycrystalline regions 220 and 222. In the illustrated embodiment, conductive contacts 104 are directly disposed in a plurality of contact openings disposed in the dielectric layer 224 and are coupled to the plurality of n-type doped polysilicon regions 220 and to the plurality of p-type doped polysilicon regions 222. The plurality of n-type doped polysilicon regions 220 and the plurality of p-type doped polysilicon regions 222 can, in one embodiment, provide emitter regions for the solar cell 100B. Thus, in an embodiment, the conductive contacts 104 are disposed on the emitter regions. In an embodiment, the conductive contacts 104 are back contacts for a back-contact solar cell and are situated on a surface of the solar cell opposing a light receiving surface (direction provided as 201 in FIG. 1B) of the solar cell 100B. Furthermore, in one embodiment, the emitter regions are formed on a thin or tunnel dielectric layer 202. In one embodiment in which the emitter regions are formed from an amorphous silicon layer, the amorphous silicon emitters are disposed on an intrinsic amorphous silicon layer.

FIG. 1B illustrates a portion of the solar cell 100B having one dielectric layer 224 disposed over the polysilicon regions 220 and 222, but other embodiments may not include dielectric layers, or may include more than one dielectric layer. In an embodiment with one or more dielectric layers disposed over the polysilicon regions 220 and 222, a copper layer of the conductive contacts directly contacts the polycrystalline silicon layer through the gaps or contact openings in the one or more dielectric layers.

Thus, FIG. 1B illustrates a solar cell having conductive contacts formed on emitter regions formed above a substrate. In another embodiment, a solar cell includes conductive contacts disposed directly on emitter regions formed in a substrate of the solar cell. For example, FIG. 1C illustrates a cross-sectional view of a portion of a solar cell having conductive contacts formed on emitter regions formed in a substrate, in accordance with an embodiment of the present disclosure.

Referring to FIG. 1C, a portion of a solar cell 100C includes a patterned dielectric layer 124 disposed above a plurality of n-type doped diffusion regions 120, a plurality of p-type doped diffusion regions 122, and on portions of a substrate 100, such as a bulk crystalline (e.g., mono crystalline) silicon substrate. Conductive contacts 104 are disposed in a plurality of contact openings disposed in the dielectric layer 124 and are coupled to the plurality of n-type doped diffusion regions 120 and to the plurality of p-type doped diffusion regions 122.

In an embodiment, the conductive contacts 104 include a copper layer that directly contacts the substrate of the solar cell 100C. In one embodiment with a monocrystalline silicon substrate, the copper layer of the conductive contacts 104 directly contacts the monocrystalline silicon substrate. For example, in an embodiment, the diffusion regions 120 and 122 are formed by doping regions of a silicon substrate with n-type dopants and p-type dopants, respectively. Furthermore, the plurality of n-type doped diffusion regions 120 and the plurality of p-type doped diffusion regions 122 can, in one embodiment, provide emitter regions for the solar cell 100C. Thus, in an embodiment, the conductive contacts 104 are disposed on the emitter regions. In an embodiment, the conductive contacts 104 are back contacts for a back-contact solar cell and are situated on a surface of the solar cell opposing a light receiving surface, such as opposing a texturized light receiving surface 101, as depicted in FIG. 1C. In an embodiment, referring again to FIG. 1C, each of the conductive contacts 104 includes a copper layer disposed on the emitter regions (i.e., diffusion regions) in direct contact with the substrate of the solar cell 100C. The conductive contacts 104 may be similar to or the same as the conductive contacts 104 described above in association with FIGS. 1A and 1B.

Although certain materials are described specifically above with reference to FIGS. 1A and 1B, some materials may be readily substituted with others with other such embodiments remaining within the spirit and scope of embodiments of the present disclosure. For example, in an embodiment, a different material substrate, such as a group III-V material substrate, can be used instead of a silicon substrate.

Furthermore, the formed contacts need not be formed directly on a bulk substrate, as was described in FIG. 1C. For example, in one embodiment, conductive contacts such as those described above are formed on semiconducting regions formed above (e.g., on a back side of) as bulk substrate, as was described for FIG. 1B.

Like FIG. 1B, FIG. 1C illustrates a portion of the solar cell 100C having one dielectric layer 124, but other embodiments may not include dielectric layers, or may include more than one dielectric layer disposed over the substrate 100. In one embodiment with one or more dielectric layers disposed over the substrate 100, a copper layer of the conductive contacts directly contacts the monocrystalline silicon substrate through gaps or contact openings in the one or more dielectric layers.

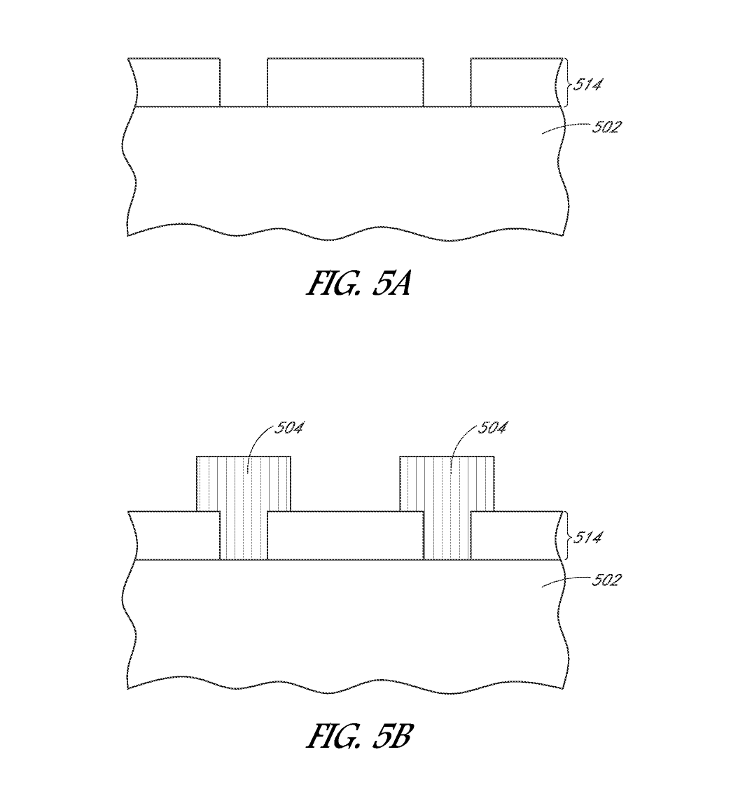

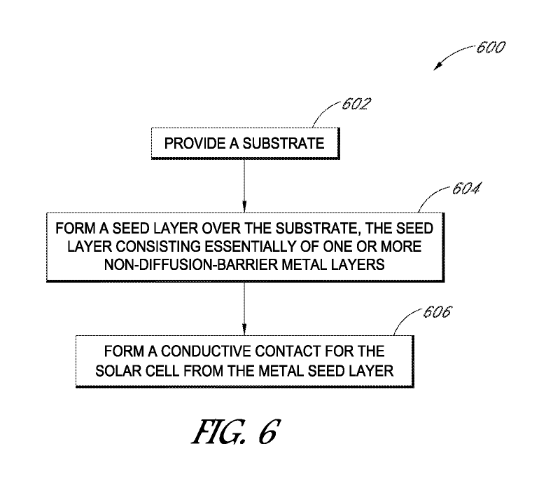

FIGS. 1A-1C illustrate portions of solar cells with conductive contacts disposed directly on a substrate, without metal seed layers, according to embodiments of the disclosure. An exemplary fabrication process for forming solar cells such as the solar cells illustrated in FIGS. 1A-1C is described below with reference to FIGS. 4, 5A, and 5B.

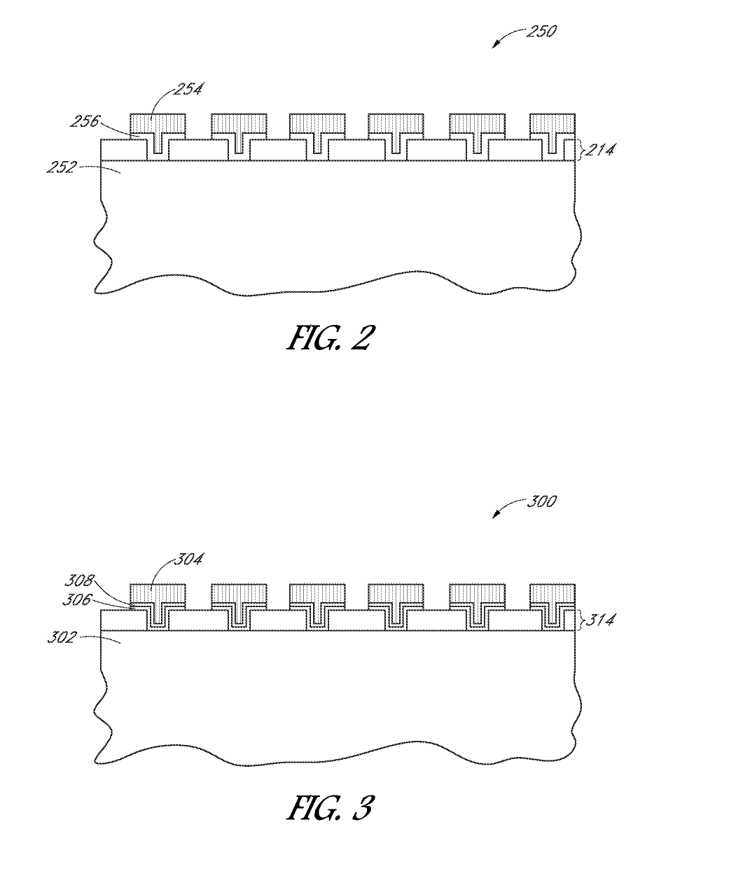

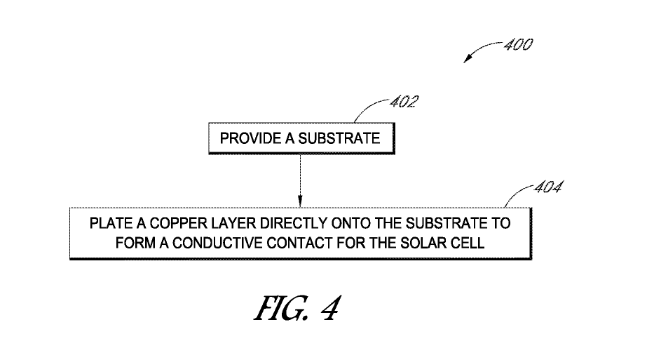

FIGS. 2 and 3 illustrate example solar cells with conductive contacts including one or more metal seed layers disposed on a substrate, according to embodiments of the disclosure. For example, FIG. 2 illustrates a cross-sectional view of a portion of a solar cell having conductive contacts including a metal seed layer disposed on a substrate, in accordance with an embodiment of the present disclosure.

A portion of the solar cell 250 includes a substrate 252. A seed layer 256 is disposed directly on the substrate 252. In one embodiment, the seed layer 256 consists essentially of one or more non-diffusion-barrier metal layers. Thus, in one such embodiment, the seed layer 256 includes one or more metal layers without an intervening diffusion-barrier metal layer. Conductive contacts 254 include a copper layer disposed directly on the seed layer 256.

In one embodiment, the substrate includes a monocrystalline silicon substrate with a polycrystalline silicon layer disposed in or above the monocrystalline silicon substrate. For example, the conductive contacts 254 may be formed on emitter regions formed above a substrate, such as described above with respect to FIG. 1B. In one such embodiment, the seed layer 256 directly contacts the polycrystalline silicon layer. The substrate 252 may further include one or more dielectric layers disposed over the polycrystalline silicon layer, such as the patterned dielectric layer 214. In one such embodiment, the seed layer 256 directly contacts the polycrystalline silicon layer through gaps or contact openings in the dielectric layer 214.

In another embodiment, the substrate 252 includes a monocrystalline silicon substrate, and the seed layer 256 directly contacts the monocrystalline silicon substrate. For example, the conductive contacts 254 can be formed on emitter regions formed in a substrate such as described above with respect to FIG. 1C. The substrate 252 may further include one or more dielectric layers disposed over the monocrystalline silicon layer, such as the patterned dielectric layer 214. In one such embodiment, the seed layer directly contacts the monocrystalline silicon substrate through gaps or contact openings in the dielectric layer 214. Thus, in embodiments, the substrate over which the seed layer 256 is disposed may include various semiconductor and/or dielectric layers.

The metal seed layer 256 can include, for example, a copper seed layer, an aluminum seed layer, a silver seed layer, a nickel seed layer, or any other non-diffusion-barrier metal layer. A “non-diffusion-barrier metal” is a metal that does not have low copper diffusivity, such as copper, aluminum, silver, or any other non-diffusion-barrier metal. In one embodiment, a copper seed layer is disposed on and directly contacts the substrate 302, and the conductive contacts 304 include a copper layer disposed directly on the copper seed layer.

According to an embodiment, the seed layer 256 includes multiple metal seed layers such as, as illustrated in FIG. 3. FIG. 3 illustrates a cross-sectional view of a portion of a solar cell having conductive contacts including multiple metal seed layers disposed on a substrate, in accordance with an embodiment of the present disclosure. A portion of a solar cell 300 includes a substrate 302. The substrate 302 can be similar to, or the same, as the substrates discussed above (e.g., the substrate 102 of FIG. 1A). As illustrated in FIG. 3, a dielectric layer 314 is disposed over the substrate 302, and the seed layer 306 contacts the substrate 302 through gaps or contact openings in the dielectric layer 314.

Metal seed layers 306 and 308 are disposed over the substrate 302. As illustrated in FIG. 3, a first metal seed layer 306 is directly contacting the substrate 302. A second metal seed layer 308 is directly contacting the first metal seed layer 306 and the conductive contact 304. The metal seed layers 306 and 308 may include, for example, one or more of a copper seed layer, an aluminum seed layer, and a silver seed layer, or any other non-diffusion-barrier metal layer.

In one embodiment, the first seed layer 306 is an aluminum or silver seed layer disposed on and directly contacting the substrate 302. Aluminum enables forming a good electrical contact with both p-type and n-type silicon. Additionally, an aluminum seed layer can have the benefit of increasing reflection of light back into the solar cell. In one such embodiment, the second metal seed layer 308 that directly contacts the first metal seed layer 306 is a copper seed layer. In one such embodiment, the copper seed layer also directly contacts a copper layer of the conductive contacts 304. A copper seed layer can enable ease of plating the copper layer of the conductive contacts 304. In other embodiments, the metal seed layers 306 and 308 may include other non-diffusion-barrier metal layers.

Although FIG. 3 illustrates conductive contacts 304 formed from two metal seed layers, other embodiment may include more than two metal seed layers. For example, in one embodiment, an aluminum seed layer is disposed directly on the substrate 302, a nickel seed layer is disposed directly on the aluminum seed layer, and a copper seed layer is disposed directly on the nickel seed layer. Other embodiments can include no metal seed layers (as described above with respect to FIGS. 1A-1C), or a single metal seed layer (as described with respect to FIG. 2).

FIG. 4 is a flowchart illustrating operations in a method of fabricating a solar cell, in accordance with an embodiment of the present disclosure. FIGS. 5A and 5B illustrate cross-sectional views of the operations of the flowchart 400 of FIG. 4, in accordance with an embodiment of the present disclosure.

Referring to FIG. 5A, and to corresponding operation 402 of the flowchart 400, a method of fabricating a solar cell involves providing a substrate 502. As explained above, providing the substrate can involve providing one or more semiconducting and/or dielectric layers. For example, providing the substrate can involve providing a monocrystalline silicon substrate with a polycrystalline silicon layer disposed in or above the monocrystalline silicon substrate. In another example, providing the substrate can involve providing a monocrystalline silicon substrate. Providing the substrate may further involve providing one or more patterned dielectric layers disposed over the monocrystalline silicon substrate and/or the polysilicon layer. As illustrated in FIGS. 5A and 5B, a patterned dielectric layer 514 is disposed over the substrate 502.

Referring to FIG. 5B, and to corresponding operation 404 of the flowchart 400, the method further involves plating a copper layer 504 directly onto the substrate 502 to form a conductive contact. Other embodiments may involve techniques other than plating to form the copper layer 504 directly onto the substrate 502 to form the conductive contact. In an embodiment with a monocrystalline silicon substrate with a polycrystalline silicon layer disposed in or above the monocrystalline silicon substrate, plating the copper layer may involve plating the copper layer directly onto the polycrystalline silicon layer. In an embodiment with a monocrystalline silicon substrate, plating the copper layer may involve electroplating the copper layer directly onto the monocrystalline silicon substrate. In other embodiments, plating the copper layer may involve any other suitable method of forming the conductive contacts. In an embodiment with one or more dielectric layers disposed over the polycrystalline silicon layer and/or monocrystalline substrate, such as the dielectric layer 514, the plated copper layer may contact underlying silicon through gaps or contact openings in the dielectric layer 514.

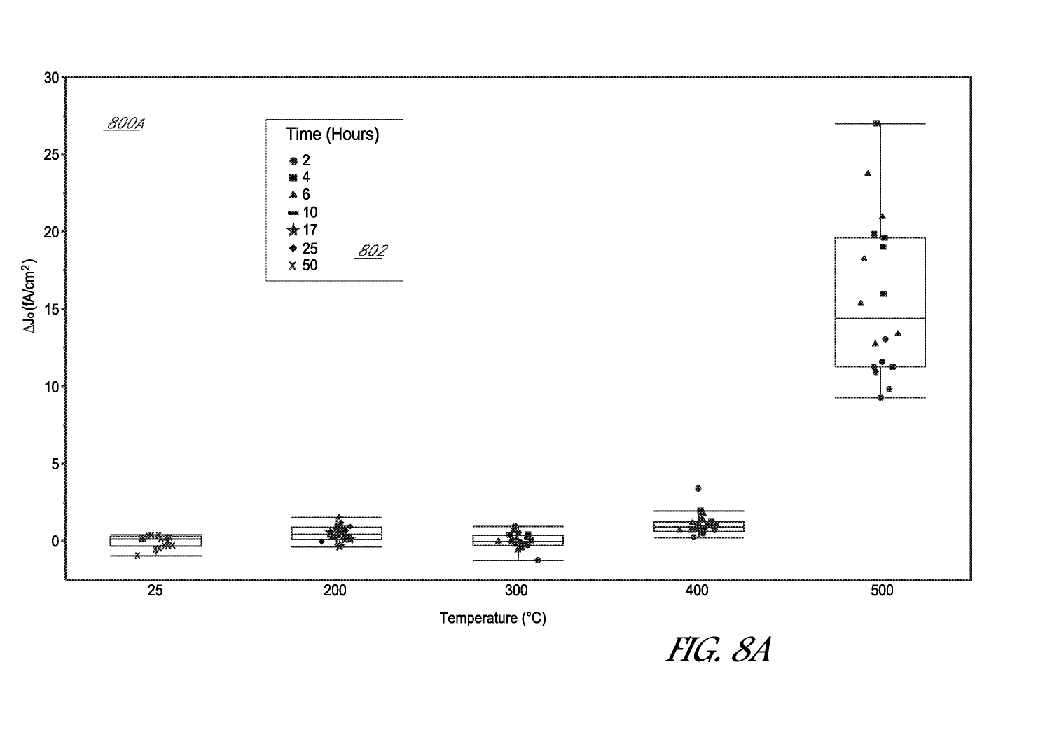

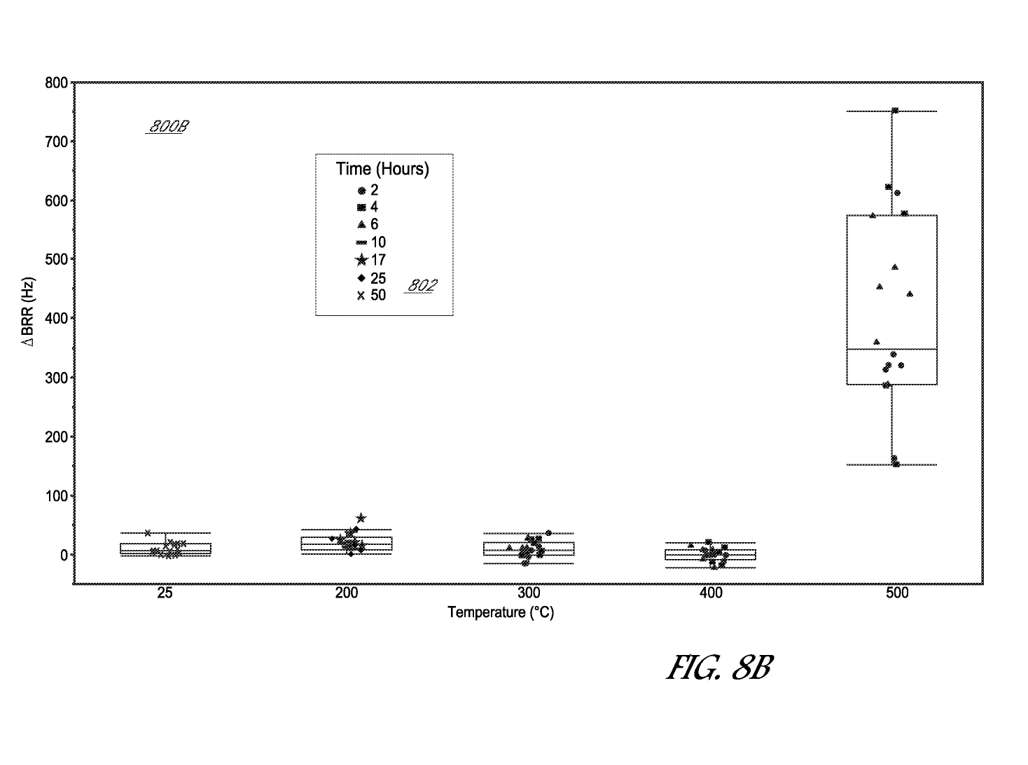

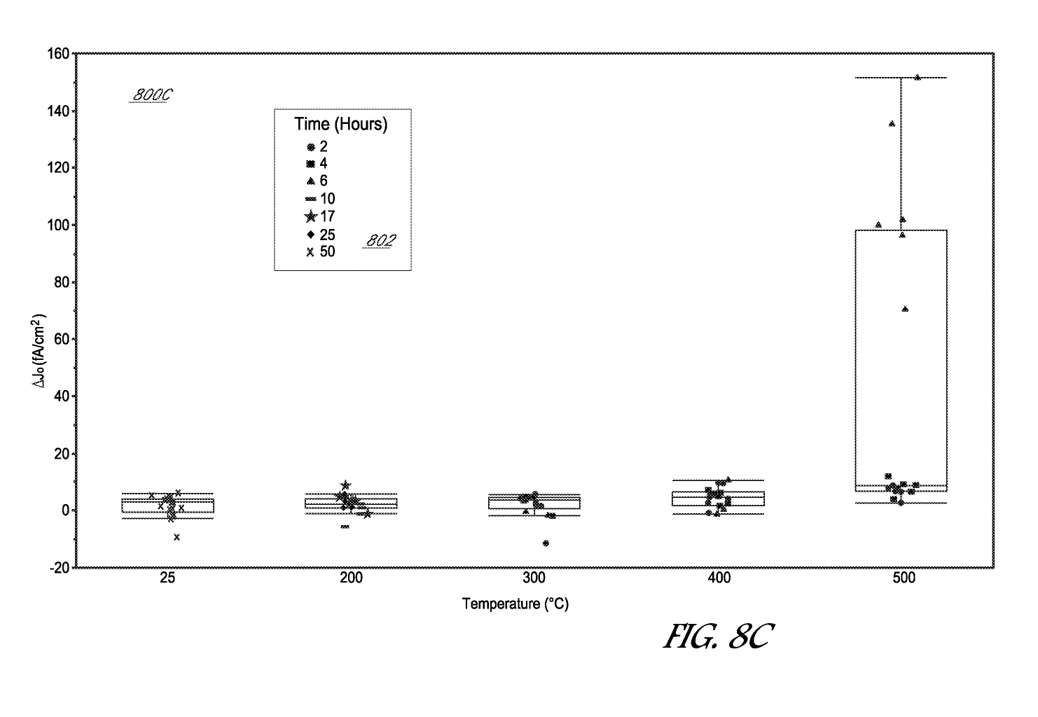

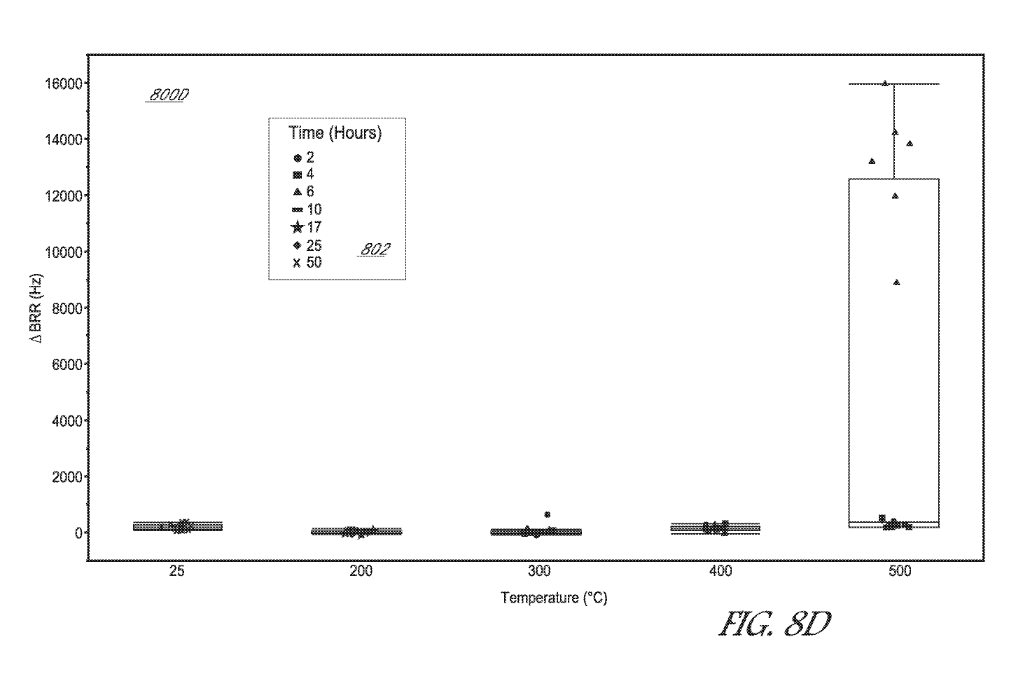

The method may further involve annealing the copper layer. Annealing the copper layer enables formation of a good contact between the copper layer and the substrate. In one embodiment, annealing the copper layer may involve heating the copper layer to a temperature that is greater than 50° C. and less than 500° C. In one such embodiment, the copper layer is heated to a temperature in a range of 50 to 450° C. According to embodiments, heating the copper layer to a temperature in a range of 50 to 450° C. can enable formation of a good contact without causing significant copper migration into the silicon Annealing at temperatures higher than 500° C. may result in migration of sufficient copper into the silicon to short contacts on the solar cells or cause other device defects. FIGS. 8A-8D illustrate graphs showing the effects of annealing at different temperatures for different lengths of time, according to an embodiment. In one embodiment, the amount of time the copper layer is annealed depends on the annealing temperature. A higher temperature (e.g., 500° C.) may involve annealing the copper layer for 10-30 minutes. A lower temperature (e.g., 300° C.) may involve annealing the copper layer for greater than 30 minutes (e.g., an hour). Other embodiments may involve other temperatures and annealing times. Annealing the copper layer at lower temperatures and/or for shorter periods of time may prevent substantial diffusion of copper into the substrate, and therefore prevent or limit damage to devices formed in the substrate.

According to an embodiment, copper atoms that diffuse into the underlying substrate tend to segregate on crystalline defects, on the surface of the substrate, or form complexes with dopant atoms. In an embodiment with a polycrystalline silicon layer disposed in or above a monocrystalline silicon substrate (e.g., such as in the portion of the solar cell 100B of FIG. 1B), the copper atoms may precipitate within the polycrystalline silicon layer, therefore preventing substantial copper contamination of the monocrystalline silicon substrate. However, other embodiments without such a polycrystalline silicon layer (e.g., the portion of the solar cell 100C of FIG. 1C) may also include conductive contacts directly on the substrate.

Thus, one embodiment includes directly plating a copper layer onto the substrate to form a conductive conduct for a solar cell. Directly plating the copper layer onto the substrate enables solar cell fabrication with fewer processing operations than existing fabrication methods. For example, embodiments may eliminate deposition and etching operations for formation of metal seed layers, and/or eliminate edge coating operations. A simpler process flow may in turn enable higher manufacturing throughput. Furthermore, directly plating the copper layer on the substrate without metal seed layers can enable a reduction of materials used to form solar cell contacts.

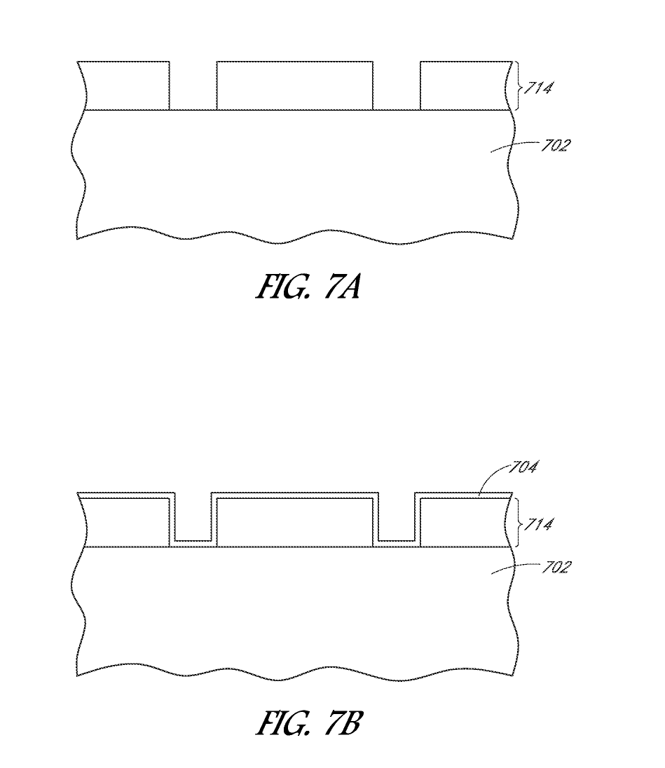

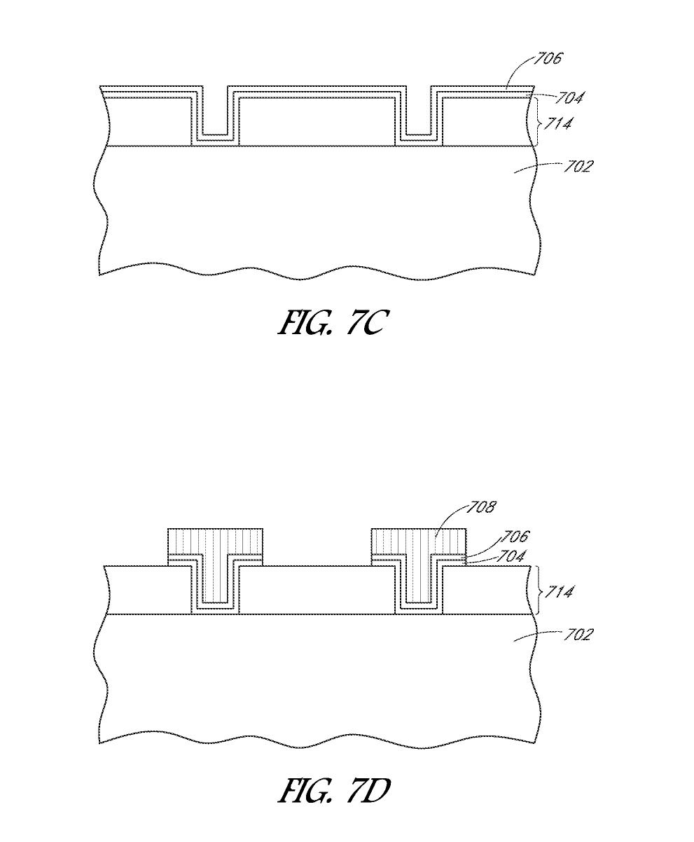

FIG. 6 is a flowchart illustrating operations in a method of fabricating a solar cell, in accordance with an embodiment of the present disclosure. FIGS. 7A, 7B, 7C, and 7D illustrate cross-sectional views of the operations of the flowchart 600 of FIG. 6, in accordance with an embodiment of the present disclosure.

Referring to FIG. 7A, and to corresponding operation 602 of the flowchart 600, a method of fabricating a solar cell involves providing a substrate 702. As explained above with respect to operation 402 of FIG. 4, providing the substrate 702 can involve providing one or more semiconducting and/or dielectric layers. As illustrated in FIGS. 7A-7D, a patterned dielectric layer 714 is disposed over the substrate 702. The substrate 702 can be similar to or the same as the substrates described above (e.g., the substrate 102 of FIG. 1A).

The method further involves forming a seed layer over the substrate, at operation 604. In an embodiment with one or more dielectric layers disposed over the polycrystalline silicon layer and/or monocrystalline substrate, such as the dielectric layer 714, the seed layer may contact underlying silicon through gaps or contact openings in the dielectric layer 714. In one embodiment, the seed layer consists essentially of one or more non-diffusion-barrier metal layers. FIG. 7B illustrates a single non-diffusion-barrier metal seed layer 704. FIG. 7C illustrates two non-diffusion-barrier metal seed layers 704 and 706. In one embodiment, forming the seed layer over the substrate may involve depositing an aluminum layer directly on the substrate to form the metal seed layer 704, and depositing a copper layer directly on the aluminum layer to form the metal seed layer 706. Deposition of the metal seed layers 704 and 706 may involve, for example, chemical vapor deposition (CVD), physical vapor deposition (PVD), or any other deposition method capable of depositing metal seed layers. Although FIGS. 7C and 7D illustrate two metal seed layers, other embodiments may involve deposition of a single metal seed layer, or more than two metal seed layers.

The method further involves forming a conductive contact 708 for the solar cell from the seed layer, at operation 606. Forming the conductive contact 708 can involve annealing the non-diffusion-barrier metal layers 704 and 706. Annealing the seed layer can involve heating the seed layer to a temperature that is greater than 50° C. and less than 500° C. In one such embodiment, the copper layer is heated to a temperature in a range of 50 to 450° C. As discussed above with respect to FIG. 4, according to embodiments, the amount of time the seed layer is annealed depends on the annealing temperature. For example, the method may involve annealing the seed layer at a temperature in a range of 50 to 450° C. for less than an hour. In one such embodiment, the method involves annealing the seed layer at a temperature in a range of 50 to 450° C. for less than ten minutes. In one embodiment, the method may further involve applying a patterned plating resist to the seed layer. The method may further involve plating a metal onto the patterned seed layer to form a plurality of metal contacts on the seed layer.

According to an embodiment, the method may further involve etching portions of the seed layers 704 and 706 between the plurality of metal contacts, to obtain the portion of the solar cell as illustrated in FIG. 7D. Etching portions of the seed layers 704 and 706 may involve wet etching, or any other method of etching the metal seed layers. In an embodiment with a seed layer that includes multiple different metal seed layers, etching may involve multiple etching operations with different chemistries. The absence of a diffusion barrier layer between the two metal seed layers may result in mixing of the metal seed layers 704 and 706 during annealing of the seed layer. Therefore, etching portions of the seed layer may involve chemistries appropriate for etching metal alloys. For example, where the metal seed layer 704 is an aluminum layer, and the metal seed layer 706 is a copper layer, etching the seed layer may involve etching using a chemistry for a copper-aluminum alloy.

FIGS. 8A-8D illustrate graphs for exemplary substrates with copper seed layers after annealing, in accordance with embodiments of the present disclosure. The graphs in FIGS. 8A-8D illustrate data from tests performed on test wafers with copper seed layers disposed directly on a substrate, similar to the portion of the solar cell illustrated in FIG. 2. The data in FIGS. 8A-8D are from measurements made on symmetrical test devices using a transient photo conductive decay (PCD) measurement setup on a well calibrated tool. Calibration of the tool was confirmed prior to making the measurements illustrated in FIGS. 8A-8D in part by testing different lots of several types of control devices, including some types of control devices having Cu diffusion barriers with well-known expected results, and some devices that were not subject to thermal stress. FIGS. 8A and 8B illustrate graphs from tests performed on test wafers having copper seed layers disposed on n-type doped polysilicon regions (e.g., the n-type doped polysilicon regions 220 of FIG. 1B). FIGS. 8C and 8D illustrate graphs from tests performed on test wafers having copper seed layers disposed on p-type doped polysilicon regions (e.g., the p-type doped polysilicon regions 222 of FIG. 1B).

FIG. 8A illustrates a graph 800A of the change in leakage current density (ΔJₒ) after annealing at different temperatures for different periods of time. The graph 800A includes data for test wafers kept at approximately room temperature (25° C.) and data for test wafers annealed at temperatures of 200° C., 300° C., 400° C., and 500° C. The legend 802 shows the symbols representing the length of time a test wafer was annealed for at a given temperature. The test wafers kept at 25° C. were measured after 50 hours. Test wafers annealed at 200° C. were measured after 10 hours, 17 hours, and 25 hours. Test wafers annealed at 300° C., 400° C., and 500° C. were measured after 2 hours, 4 hours, and 6 hours. As can be seen in the graph 800A, the test wafers held at 25° C. and the test wafers annealed at 200° C., 300° C., and 400° C. experienced little change in leakage current density. However, annealing the test wafers at 500° C. resulted in an increase in the leakage current density, which may be indicative of a reduction in quality or defective devices.

FIG. 8B illustrates a graph 800B of the change in bulk recombination rate (ABRR) of the test wafers annealed at the temperatures and times described above with respect to FIG. 8A. Similar to the graph 800A of FIG. 8A, the graph 800B shows that the test wafers did not experience a significant change in bulk recombination rate when held at 25° C. or annealed at 200° C., 300° C., and 400° C. However, the test wafers annealed at 500° C. experienced an increase in bulk recombination rate, also indicative of a reduction in quality or defective devices.

FIGS. 8C and 8D illustrate graphs comparable to those in FIGS. 8A and 8B, but for test wafers having copper seed layers disposed on p-type doped polysilicon regions. The graphs 800C and 800D include data for test wafers kept at approximately room temperature (25° C.) and data for test wafers annealed at temperatures of 200° C., 300° C., 400° C., and 500° C. The graph 800C illustrates the change in leakage current density (ΔJₒ) after annealing at different temperatures, and the graph 800D illustrates the change in bulk recombination rate (ABRR) of test wafers annealed at the temperatures and times shown in FIG. 8C. Like the graphs in FIGS. 8A and 8B, the graph 800C of FIG. 8C and the graph 800D of FIG. 8D show relatively insignificant changes to the test wafers held at 25° C. or annealed at 200° C., 300° C., and 400° C., but show greater changes when annealed at 500° C. However, even when annealed at 500° C. for shorter periods of time (e.g., two hours or four hours), graphs 800C and 800D show relatively little change in leakage current density and bulk recombination rate.

Thus, the graphs in FIGS. 8A-8D illustrate that an embodiment with a copper seed layer, but no barrier layer between the copper seed layer and the substrate, may be annealed without significantly changing the leakage current density or bulk recombination rate. For example, annealing at low temperatures (e.g., less than 500° C.), or at higher temperatures (e.g., 500° C.) but for shorter periods of time, may enable forming good contacts without significantly increasing the leakage current density or bulk recombination rate. The small changes in leakage current density and bulk recombination rate illustrated in FIGS. 8A-8D indicate that embodiments with barrier-less copper seed layers may be annealed to make solar cells contacts without causing device defects.

According to embodiments, forming a seed layer without a diffusion barrier layer enables solar cell fabrication with fewer processing operations than existing fabrication methods. For example, embodiments may eliminate deposition and etching operations for the barrier layer, and/or eliminate edge coating operations. A simpler process flow may in turn enable higher manufacturing throughput. Furthermore, forming a seed layer without a barrier layer can enable a reduction of materials used to form solar cell contacts.

Thus, approaches for forming barrier-less metal seed stacks and contacts for solar cells and the resulting solar cells have been disclosed.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

What is claimed is:

1. A solar cell comprising:
a substrate; and
a conductive contact disposed on the substrate and comprising a copper layer directly contacting the substrate.

2. The solar cell of claim 1, wherein:
the substrate comprises a monocrystalline silicon substrate with a polycrystalline silicon layer disposed in or above the monocrystalline silicon substrate; and
the copper layer directly contacts the polycrystalline silicon layer.

3. The solar cell of claim 2, wherein:
the substrate further comprises one or more dielectric layers disposed over the polycrystalline silicon layer, wherein the copper layer directly contacts the polycrystalline silicon layer through gaps in the one or more dielectric layers.

4. The solar cell of claim 1, wherein:
the substrate comprises a monocrystalline silicon substrate; and
the copper layer directly contacts the monocrystalline silicon substrate.

5. The solar cell of claim 4, wherein:
the substrate further comprises one or more dielectric layers disposed over the monocrystalline silicon substrate, wherein the copper layer directly contacts the monocrystalline silicon substrate through gaps in the one or more dielectric layers.

6. The solar cell of claim 1, wherein:
the substrate comprises a monocrystalline silicon substrate with a polycrystalline silicon layer disposed in or above the monocrystalline silicon substrate, and wherein the polycrystalline silicon layer has a doping concentration of at least 10¹⁸ per cm³.

7. A solar cell comprising:
a substrate;
a seed layer disposed directly on the substrate, the seed layer consisting essentially of one or more non-diffusion-barrier metal layers; and
a conductive contact comprising a copper layer disposed directly on the seed layer.

8. The solar cell of claim 7, wherein:
the substrate comprises a monocrystalline silicon substrate with a polycrystalline silicon layer disposed in or above the monocrystalline silicon substrate; and
the seed layer directly contacts the polycrystalline silicon layer.

9. The solar cell of claim 8, wherein the substrate further comprises one or more dielectric layers disposed over the polycrystalline silicon layer, wherein the seed layer directly contacts the polycrystalline silicon layer through gaps in the one or more dielectric layers.

10. The solar cell of claim 7, wherein:
the substrate comprises a monocrystalline silicon substrate;
the seed layer directly contacts the monocrystalline silicon substrate.

11. The solar cell of claim 10, wherein:
the substrate further comprises one or more dielectric layers disposed over the monocrystalline silicon substrate, wherein the seed layer directly contacts the monocrystalline silicon substrate through gaps in the one or more dielectric layers.

12. The solar cell of claim 7, wherein the one or more non-diffusion-barrier metal layers comprise an aluminum or silver seed layer directly contacting the substrate, and a copper seed layer directly contacting the aluminum or silver seed layer.

13. A method of fabricating a solar cell, the method comprising:
providing a substrate;
forming a seed layer over the substrate, the seed layer consisting essentially of one or more non-diffusion-barrier metal layers; and
forming a conductive contact for the solar cell from the seed layer.

14. The method of claim 13, wherein:
providing the substrate comprises providing a monocrystalline silicon substrate, and forming a polycrystalline silicon layer in or above the monocrystalline silicon substrate; and
forming the seed layer over the substrate comprises forming the seed layer directly on the polycrystalline silicon layer.

15. The method of claim 14, wherein:
providing the substrate further comprises providing one or more patterned dielectric layers disposed over the polycrystalline silicon layer; and
forming the seed layer comprises directly forming the seed layer on the polycrystalline silicon layer through gaps in the one or more patterned dielectric layers.

16. The method of claim 13, wherein:
providing the substrate comprises providing a monocrystalline silicon substrate; and
forming the seed layer comprises forming the seed layer directly on the monocrystalline silicon substrate.

17. The method of claim 16, wherein:
providing the substrate further comprises providing one or more patterned dielectric layers disposed over the monocrystalline silicon substrate; and
forming the seed layer comprises forming the seed layer directly on the monocrystalline silicon substrate through gaps in the one or more patterned dielectric layers.

18. The method of claim 13, wherein forming the conductive contact for the solar cell from the seed layer comprises annealing the seed layer at a temperature in a range of 50 to 450° C.

19. The method of claim 13, wherein:
providing the substrate comprises providing a monocrystalline silicon substrate with a polycrystalline silicon layer disposed in or above the monocrystalline silicon substrate, wherein the polycrystalline silicon layer has a doping concentration of at least 10¹⁸ per cm³.

20. The method of claim 13, wherein forming the conductive contact for the solar cell from the seed layer comprises:
annealing the seed layer;
applying a patterned plating resist to the seed layer;
plating a metal onto the patterned seed layer to form a plurality of metal contacts on the seed layer; and
etching portions of the seed layer between the plurality of metal contacts.
